(19) United States
(12) Patent Application Publication
(10) Pub. No.: US 2013/0099786 A1
(43) Pub. Date: Apr. 25, 2013

(54) PARALLEL MAGNETIC RESONANCE IMAGING USING UNDERSAMPLED COIL DATA FOR COIL SENSITIVITY ESTIMATION

(71) Applicants: Feng Huang, Gainesville, FL (US); Mariya Doneva, Hamburg (DE); Peter Boernert, Hamburg (DE); Julien Senegas, Hamburg (DE)

(72) Inventors: Feng Huang, Gainesville, FL (US); Mariya Doneva, Hamburg (DE); Peter Boernert, Hamburg (DE); Julien Senegas, Hamburg (DE)

(73) Assignee: KONINKLIJKE PHILIPS ELECTRONICS N.V., EINDHOVEN (NL)

(21) Appl. No.: 13/805,813

(22) PCT Filed: Jun. 22, 2011
(86) PCT No.: PCT/IB2011/052724

§ 371 Date: Dec. 20, 2012

Related U.S. Application Data
(60) Provisional application No. 61/361,046, filed on Jul. 2, 2010.

(51) Int. Cl. G01R 33/56

(52) U.S. Cl. CPC G01R 33/56
USPC 324/309

(57) ABSTRACT

A computer program product (1344, 1346, 1348) comprising machine executable instructions for performing a method of acquiring a magnetic resonance image (1342), the method comprising the steps of: acquiring (100, 200, 300) a set of coil array data (1334) of an imaging volume (1304) using a coil array (1314), wherein the set of coil array data comprises coil element data acquired for each antenna element (1316) of the coil array; acquiring (102, 202, 302) body coil data (1336) of the imaging volume with a body coil (1318), wherein the body coil data and/or the array coil data is sub-sampled; reconstructing (104, 204, 206, 304, 306, 308) a set of coil sensitivity maps (1338) using the set of coil array data and the body coil data, wherein there is a coil sensitivity map for each antenna element of the coil array; acquiring (106, 208, 310) magnetic resonance imaging data (1340) of the imaging volume using a parallel imaging method (1332); and reconstructing (108, 210, 312) the magnetic resonance image using the magnetic resonance imaging data and the set of coil sensitivity maps.

### TECHNICAL FIELD

The invention relates to magnetic resonance imaging, in particular to acquiring magnetic resonance images using a parallel imaging method.

### BACKGROUND OF THE INVENTION

In magnetic resonance imaging there is a family of image reconstruction techniques or methods for reconstructing magnetic resonance images known as parallel imaging techniques. An example of which is the sensitivity encoding or SENSE reconstruction technique. In SENSE the conventional Fourier encoding is reduced by utilizing spatial information about the individual antenna element of a multi element coil array. This reduction in the Fourier encoding allows the magnetic resonance imaging data necessary for a magnetic resonance image to be acquired more rapidly.

To perform high quality SENSE reconstruction an accurate knowledge of the receive coil sensitivities is required. Coil sensitivities are estimated from a low resolution reference scan, in which data of the coil array and the body coil are acquired in an interleaved fashion. A more accurate estimation of the coil sensitivities can be obtained from high resolution data; however, this requires additional scan time, which is not desired in terms of scan efficiency and might increase the risk of motion artifacts.

The journal article Lustig, Donoho, and Pauly, ‘Sparse MRI: The application of Compressed Sensing for Rapid MR Imaging,’ Magnetic Resonance in Medicine 58: 1182-1195 (2007) describes the mathematical theory behind compressed sensing for magnetic resonance imaging. Essentially images with a sparse representation can be recovered from randomly undersampled k-space data. This article demonstrates this technique for improved spatial resolution and accelerated acquisition for multislice fast spin echo brain imaging and 3D contrast enhanced angiography.

### SUMMARY OF THE INVENTION

The invention provides for a computer program product, a computer-implemented method, and a magnetic resonance imaging system in the independent claims. Embodiments are given in the dependent claims.

In order to use SENSE or other parallel imaging techniques detailed knowledge of the sensitivities for the individual antenna elements of the coil array is necessary. It is assumed that coil sensitivity maps are smooth functions in space. Low resolution estimates might be sufficient for a large part of the maps. But errors might appear at the object edges and cause artifacts in the SENSE reconstruction. The main reason for this is that the high spatial frequencies in the coil sensitivities, especially at those edges, are not sufficiently captured. To address this problem, some embodiments of the invention may improve the spatial resolution of coil sensitivity maps without increasing the scan time by means of imaging with partially acquired data, such as compressed sensing.

In parallel Magnetic Resonance Imaging (MRI), accurate coil sensitivity estimates are required to reconstruct aliasing-free images. Generally, these are computed on the basis of fully sampled, low-resolution data, which are acquired either separately (reference pre-scan such as the COCA scan) or jointly with the under-sampled imaging data (auto-calibration). Alternatively, a joint reconstruction of images and coil sensitivities may be performed. Existing approaches exploit the a priori assumption that coil sensitivities are smooth functions to regularize the non-linear reconstruction problem for example by using a polynomial model for the sensitivities, as in JSENSE, or by penalizing their Sobolev norm using a non-linear inverse algorithm.

A ‘computer-readable storage medium’ as used herein is any storage medium which may store instructions which are executable by a processor of a computing device. The computer-readable storage medium may be a computer-readable non-transitory storage medium. The computer-readable storage medium may also be a tangible computer readable medium. In some embodiments, a computer-readable storage medium may also be able to store data which is able to be accessed by the processor of the computing device. An example of a computer-readable storage medium include, but are not limited to: a floppy disk, a magnetic hard disk drive, a solid state hard disk, flash memory, a USB thumb drive, Random Access Memory (RAM) memory, Read Only Memory (ROM) memory, an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network.

‘Computer memory’ or ‘memory’ as used herein is an example of a computer-readable storage medium. Computer memory is any memory which is directly accessible to a processor. Examples of computer memory include, but are not limited to: RAM memory, registers, and register files.

‘Computer storage’ or ‘storage’ as used herein is an example of a computer-readable storage medium. Computer storage is any non-volatile computer-readable storage medium. Examples of computer storage include, but are not limited to: a hard disk drive, a USB thumb drive, a floppy drive, a smart card, a DVD, a CD-ROM, and a solid state hard drive. In some embodiments computer storage may also be computer memory or vice versa.

A ‘processor’ as used herein is an electronic component which is able to execute a program or machine executable instruction. References to the computing device comprising “a processor” should be interpreted as possibly containing more than one processor. The term computing device should also be interpreted to possibly refer to a collection or network of computing devices each comprising a processor. Many programs have their instructions performed by multiple processors that may be within the same computing device or which may even distributed across multiple computing device.

‘Magnetic Resonance Imaging data’ is defined herein as being the recorded measurements of radio frequency signals emitted by atomic or electronic spins by the antenna of a Magnetic resonance apparatus during a magnetic resonance imaging scan. A Magnetic Resonance Imaging (MRI) image is defined herein as being the reconstructed two or three dimensional visualization of anatomic, parametric or functional data contained within the magnetic resonance imaging data. This visualization can be performed using a computer.

In one aspect the invention provides for a computer program product comprising machine executable instructions for performing a method of acquiring a magnetic resonance image. The computer program product may be stored on a computer-readable storage medium. The method comprises the step of acquiring a set of coil array data of an imaging volume using a coil array. A coil array as used herein is a multi-element magnetic resonance imaging coil. The coil array may function as a transmit and/or receive coil for performing magnetic resonance imaging. Coil array data as used herein is magnetic resonance imaging data acquired using the coil array. Each part of the coil array data is magnetic resonance imaging data from each individual coil array. The set of coil array data comprises coil element data acquired for each antenna element of the coil array. ‘Coil element data’ as used herein encompasses magnetic resonance imaging data acquired by an antenna element.

The method further comprises the step of acquiring body coil data of the imaging volume with a body coil. A ‘body coil’ as used herein encompasses a magnetic resonance imaging coil which images a large region. A ‘coil array’ as used herein encompasses a magnetic resonance imaging coil which comprises multiple antenna elements.

In some embodiments the body coil may comprise multiple antenna elements used collectively. In this case the data from the multiple antenna elements may be combined to form a single virtual coil.

The body coil may be used as reference to compute coil sensitivities, i.e. the coil sensitivities of the coil array are computed relative to the body coil, assuming that the sensitivity of the body coil is homogeneous over the field of view. Any other coil having an homogeneous coil sensitivity over the desired field of view could be used instead, including a virtual coil as described above.

The body coil data and/or array coil data is sub-sampled in k-space. This is advantageous because it may be possible to accurately image or acquire magnetic resonance imaging data which represents the imaging volume by using key elements or a smaller subset of k-space.

One interpretation of ‘sub-sampling’ as used herein encompasses ignoring or removing the high-frequency component of k-space. For example, for a target k-space sampling matrix of dimension N (N refers here to a “high-resolution” sampling strategy, as opposed to prior art), fewer than N k-space samples are acquired, for the body coil and/or for the coil array data. In this interpretation of sub-sampling, the high frequency components are missing

Another interpretation of ‘sub-sampling’ as used herein encompasses undersampling. In undersampling selected frequency components are not sampled. The components which are not sampled may be based on uniform or non-uniform under-sampling patterns or distributions.

The method further comprises the step of reconstructing a set of coil sensitivity maps using the set of coil array data and the body coil data. When performing parallel imaging methods such as SENSE the sensitivity of the individual coil elements of the coil array needed to be known. There is a coil sensitivity map which is reconstructed for each antenna element of the coil array. The method further comprises the step of acquiring magnetic resonance imaging data of the imaging volume using a parallel imaging method. As used herein a parallel imaging method encompasses imaging methods for magnetic resonance imaging in which spatial information related to the coils of a coil array are utilized for reducing the conventional Fourier encoding. Parallel imaging methods are able to accelerate and require less time for acquiring magnetic resonance imaging data which can be reconstructed into magnetic resonance images. Alternatively, keeping total scanning time fixed parallel imaging methods allows to increase the spatial resolution.

The method further comprises the step of reconstructing the magnetic resonance image using the magnetic resonance imaging data and the set of coil sensitivity maps. This method as performed by the computer program product is advantageous because the body coil data has been undersampled in k-space. This reduces the amount of time required to acquire the magnetic resonance imaging data.

In another embodiment the set of coil array data is undersampled in k-space. This embodiment is particularly advantageous because the set of coil array data has been undersampled in addition to the body coil data being undersampled. This may lead to a significant saving in the amount of time required to acquire magnetic resonance imaging data using a parallel imaging method. The coil element data corresponding to each element of the coil array may be undersampled in k-space to the same degree or

In another embodiment the coil element data and the body coil data are undersampled to a different degree. This embodiment may be advantageous because it may be possible to reconstruct either the coil element data or the body coil data using the data which is sampled more than the other. For instance if the body coil data is more undersampled in k-space than the coil element data then the coil element data may be used to partially reconstruct the body coil data. This may be advantageous because this may further reduce the amount of time to perform the method.

In another embodiment the undersampling of k-space of the body coil and/or array coil is non-uniformly distributed in k-space. For instance the k-space from the body coil may be densely sampled for low values of k-space and densely sampled for higher values in k-space.

In another embodiment the set of coil sensitivity maps is reconstructed using a regularization technique. One example of a regularization technique is the use of a mathematical smoothing function such as fitting a polynomial, Fourier series, or spline. For these mathematical smoothing functions a low number of parameters is typically used. Another example of a regularization technique is the use of a regularization constraint with a L0, L1 or L2 norm in the minimization problem.

In another embodiment the set of coil sensitivity maps is reconstructed using a sparsity constraint algorithm. The term ‘sparsity constraint algorithm’ encompasses an algorithm which uses a sparsifying transform such as wavelets or finite differences and has a constraint component which enforces consistency with measurements that are made in k-space.

In another embodiment the sparsity constraint algorithm is performed on the subsets of the set of coil array data. Subsets are determined by grouping coil element data from physically adjacent antenna elements of the coil array. This embodiment is particularly advantageous because the antenna elements of the coil array obtain magnetic resonance imaging data at relatively short range. That is to say that an antenna element acquires magnetic resonance imaging data from a portion of the imaging volume. That may be therefore beneficial to compare only adjacent coil element data and performing the algorithm to reduce the calculation time. Magnetic resonance imaging data is sampled in Fourier space or k-space so the volume from which magnetic resonance data is acquired is not defined by a boundary in regular space. However, it is expected that adjacent antenna elements of the coil array acquire magnetic resonance imaging data that is more highly correlated than antenna elements which are not adjacent to each other.

In another embodiment the k-space of the body coil data is undersampled by acquiring k-space data from a central kernel using the body coil. This embodiment is advantageous because the k-space data can be acquired faster, but the higher spatial resolution information can be reconstructed using data from coil array. For instance the kernel may be a region of k-space which is predetermined and has a low value of k. The body coil data for this kernel is then acquired. Since the kernel represents the low k-space a relatively uniform and accurate image is or may be reconstructed. However, because the k-space has been restricted to a central kernel high resolution items in the image may be washed out or not present. The body coil data may be more completely reconstructed by comparing the body coil data in this embodiment with the coil element data acquired for each antenna element of the coil array. High k-space data from the coil array may be used to reconstruct or calculate a composite image which contains the higher k-space data.

In another embodiment the set of coil sensitivity maps and a composite image are jointly estimated using a non-linear estimation. In some embodiments, the non-linear estimation may be a non-linear least squares estimation. In some embodiments the higher k-space data may be added to the body coil data using the non-linear least-squares estimation.

Alternatively all k-space data, from both the body coil and the coil array, may be used to jointly estimate coil sensitivities and a composite image with resolution of identical to images reconstructed from the coil array data.

In another embodiment the method further comprises the step of calculating a set of weighing factors for each of the antenna elements of the coil array using the k-space data from the central kernel. The method further comprises the step of calculating the composite image by applying the set of weighing factors to each image of the set of coil array images. The set of coil array images is reconstructed from the set of coil array data. The set of coil sensitivity maps is calculated using the composite image and the set of coil array data. This embodiment further clarifies how the coil sensitivity map and the composite image may be jointly estimated.

In another embodiment the parallel imaging method is SENSE.

In another embodiment the parallel imaging method is PARS.

In another embodiment the parallel imaging method is simultaneous acquisition of spatial harmonics, or GRAPPA.

In another embodiment the undersampling of the k-space is performed using a predetermined sampling pattern. A predetermined sampling pattern may be used for undersampling the set of coil array data and/or the body coil data.

In another embodiment the undersampling of the k-space is performed using a random sampling pattern. A random sampling pattern may be used to undersample the k-space of the set of coil array data and/or the body coil data.

In another embodiment the undersampling of the k-space is performed using a sampling method where the k-space elements are determined by a Poisson-disk distribution. Such a sampling method may be used for undersampling the set of coil array data and/or the body coil data.

In another embodiment the undersampling of the k-space is performed by sampling fully a kernel of k-space below a predetermined value of k and sparsely sampling above the value of k. Such a sampling method may be used for undersampling the k-space of the set of coil array data and/or the body coil data.

It should be noted that the undersampling of the set of coil array data may be undersampled using a different method from that which is used to undersample the body coil data.

In another aspect the invention provides for a computer-implemented method of acquiring a magnetic resonance imaging. The method comprises the step of acquiring a set of coil array data of an imaging volume using a coil array. The set of coil array data comprises coil element data acquired for each antenna element of the coil array. The method further comprises the step of acquiring body coil data of an imaging volume with a body coil. The body coil and/or coil array data is sub-sampled in k-space. The method further comprises the step of reconstructing a set of coil sensitivity maps using the set of coil array data and the body coil data. There is a coil sensitivity map for each antenna element of the coil array. The method further comprises the step of acquiring magnetic resonance imaging data of the imaging volume using a parallel imaging method. The method further comprises the step of reconstructing the magnetic resonance image using the magnetic resonance imaging data and the set of coil sensitivity maps. The advantages of this method have been previously discussed in the context of the computer program product.

In another aspect the invention provides for a magnetic resonance imaging system. The magnetic resonance imaging system comprises a magnetic resonance imaging magnet. The magnetic resonance imaging system further comprises a magnetic field gradient coil. The magnetic resonance imaging system further comprises a gradient coil power supply for supplying current to the magnetic field gradient coil. The magnetic resonance imaging system further comprises a radio frequency system for acquiring magnetic resonance imaging data. The radio frequency system is adapted to connect to a body coil and a coil array. The magnetic resonance imaging system further comprises a computer system comprising a processor. The computer system is adapted for constructing images from the magnetic resonance imaging data and for controlling the operation of the magnetic resonance imaging system.

The magnetic resonance imaging system further comprises a computer-readable storage medium containing instructions for execution by the processor wherein when executed cause the processor to perform the step of acquiring a set of coil array data of the imaging volume using a coil array. The set of coil array data comprises coil element data acquired for each antenna element of the coil array. The processor further performs the step of acquiring body coil data of the imaging volume with a body coil. The body coil and/or coil array data is sub-sampled in k-space. The processor further performs the step of reconstructing a set of coil sensitivity maps using the set of coil element data and the coil array data. There is a coil sensitivity map for each antenna element of the coil array. The processor further performs the step of acquiring magnetic resonance imaging data of the imaging volume using a parallel imaging method. The processor further performs the step of reconstructing the magnetic resonance image using the magnetic resonance imaging data and the set of coil sensitivity maps. The advantages of this magnetic resonance imaging system have been previously discussed in the context of the computer program product.

### BRIEF DESCRIPTION OF THE DRAWINGS

In the following preferred embodiments of the invention will be described, by way of example only, and with reference to the drawings in which:

FIG. 1 shows a block diagram which illustrates an embodiment of a method according to the invention;

FIG. 2 shows a block diagram which illustrates a further embodiment of a method according to the invention;

FIG. 3 shows a block diagram which illustrates a further embodiment of a method according to the invention;

FIG. 4 shows an example of a k-space sampling pattern;

FIG. 5 shows a collection of images which are used to illustrate the effectiveness of an embodiment of the invention;

FIG. 6 shows MRI images showing a slice through a subject's brain;

FIG. 7 shows a comparison of the phase of the images shown in FIG. 6;

FIG. 8 illustrates the location of k-space samples acquired in a COCA scan;

FIG. 9 illustrates the location of k-space samples acquired in a scan according to an embodiment of the invention;

FIG. 10 shows a SENSE reconstruction from a fourfold undersampled dataset with the standard coil sensitivities derived from a COCA scan;

FIG. 11 shows the same image as shown in FIG. 10 except the alternative coil sensitivities are derived using an embodiment of the invention;

FIG. 12 shows the same image as shown in FIG. 10 except the alternative coil sensitivities are derived using a further embodiment of the invention; and

FIG. 13 shows a functional diagram illustrating a magnetic resonance imaging system according to an embodiment of the invention.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

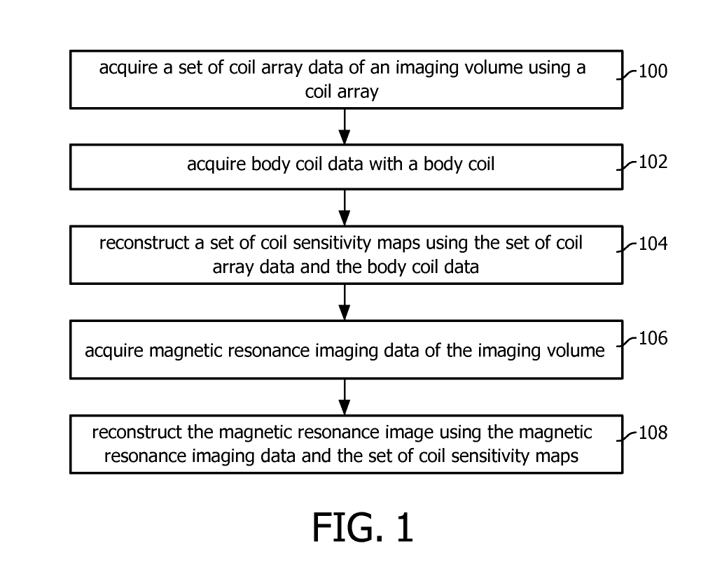

FIG. 1 shows a block diagram which illustrates an embodiment of a method according to the invention. This method may be implemented as a computer-implemented method, a computer program product, and also as instructions stored on a computer-readable storage medium. In step 100 a set of coil array data is acquired of an imaging volume using the coil array. In step 102 body coil data is acquired with a body coil. Either step 100 or 102 may be performed first. During steps 100 and 102 the body coil data and/or the coil array data are sub-sampled. In step 104 a set of coil sensitivity maps is reconstructed using the set of coil array data and the body coil data. In step 106 magnetic resonance imaging data is acquired of the imaging volume. In step 108 the magnetic resonance image is reconstructed using the magnetic resonance imaging data and the set of coil sensitivity maps.

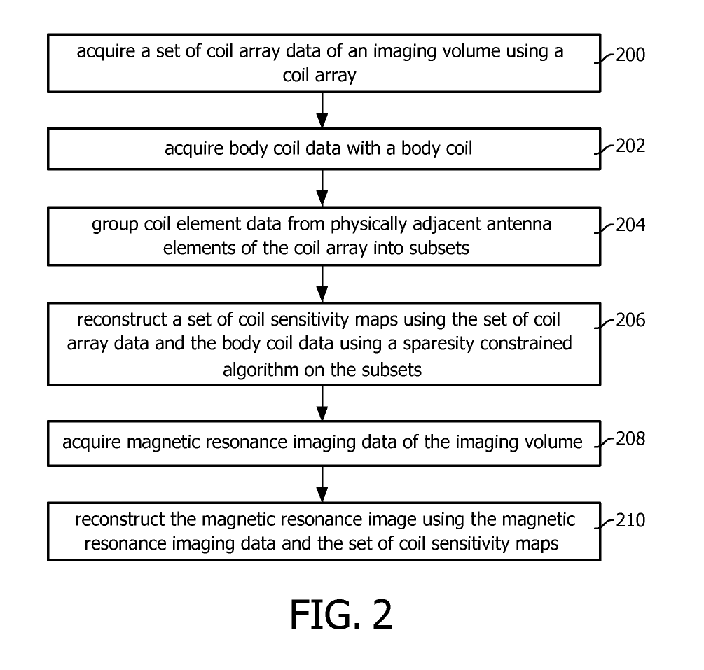

FIG. 2 shows a block diagram which illustrates a further embodiment of a method according to the invention. This method may also be implemented as a computer-implemented method, a computer program product or as instructions stored on a computer-readable storage medium. In step 200 a set of coil array data is acquired of an imaging volume using a coil array. In step 202 body coil data is acquired with a body coil. Either step 200 or 202 may be performed first. During steps 200 and 202 the body coil data and/or the coil array data are sub-sampled. In step 204 the coil element data from physically adjacent antenna elements is grouped into subsets. In step 206 a set of coil sensitivity maps is reconstructed using the set of coil array data and the body coil data using a sparsely constrained algorithm on the subsets. In step 208 magnetic resonance imaging data of the imaging volume is acquired. Finally in step 210 the magnetic resonance image is reconstructed using the magnetic resonance imaging data and the set of coil sensitivity maps.

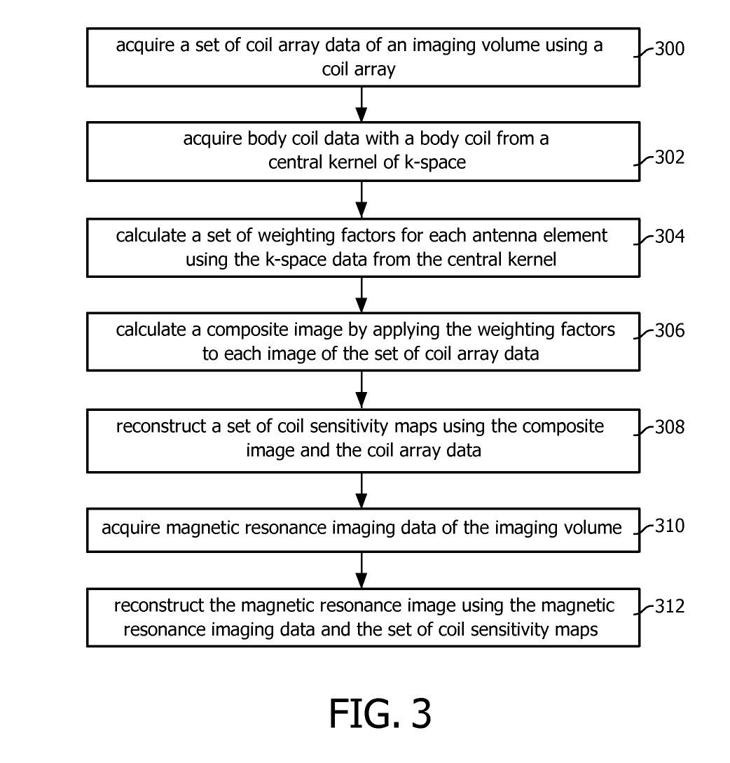

FIG. 3 shows a block diagram which illustrates a further embodiment of the method. The method may be implemented as a computer-implemented method, a computer program product, or may be implemented as instructions stored on a computer-readable storage medium. In step 300 a set of coil array data is acquired of an imaging volume using a coil array. In step 302 body coil data is acquired with a body coil. Either step 300 or 302 may be performed first. During steps 300 and 302 the body coil data and/or the coil array data are sub-sampled. The body coil data is acquired from at least a central kernel of k-space. In step 304 a set of weighing factors is calculated for each antenna element using the k-space data from the central kernel. In step 306 a composite image is calculated by applying the weighing factors to each image of the set of coil array data. The composite image is constructed from the body coil data and the set of coil array data. In step 308 a set of coil sensitivity maps is reconstructed using the composite image and the coil array data. In step 310 magnetic resonance imaging data is acquired of the imaging volume. In step 312 the magnetic resonance image is reconstructed using the magnetic resonance imaging data and the set of coil sensitivity maps.

### Technique 1:

In conventional coil sensitivity mapping fully sampled low-resolution images are acquired with the coil array and the body coil. To improve the resolution without increasing the scan time, it is the idea to cover a larger portion of k-space and undersample the k-space to avoid prolonged scan times. The undersampling could be performed in a pseudo-random fashion (e.g. Poisson-Disk sampling) in the phase encoding direction with fully sampling a small portion of the central part of k-space.

The simplest way to use compressed sensing is to reconstruct the individual images for each coil element independently. The images are obtained by solving the problem:

Minimize ∥ψxₙ∥1

subject to Fᵤxₙ=yₙ|_{acq}, n=1, . . . , N (1)

where ψ is the sparsifying transform (wavelets or finite differences), xₙ is the image for single coil, yₙ|_{acq} is the corresponding k-space data vector at the acquired k-space locations, Fᵤ is the undersampled Fourier transform operator which gives the Fourier transform only at the measured k-space locations, and N is the total number of coils (all elements of the coil array plus the body coil). The first term enforces sparsity and the second term enforces consistency with the measurements.

Images obtained for the different coils contain the same magnetization distribution, weighted by the corresponding receive sensitivity. Thus, they share a common sparse support and it could be useful to reconstruct the same set of sparse coefficients for all coil elements. This can be achieved by using a joint sparsity in the reconstruction, which results in the optimization problem:

Minimize Σᵣ{square root over (Σₙ(ψxₙ(r))²)}

subject to Fᵤxₙ=yₙ|_{acq}, n=1, . . . , N (2)

The joint sparsity prevents loosing small coefficients in the reconstruction; however for large coil arrays and strongly localized coil sensitivities, this could result in worse sparsity (larger number of nonzero coefficients). In this case to ensure performance it is preferable that Eq. 2 is modified, considering the sparsity pattern only for sub-groups of all coils which consists of neighboring coils. This local joint sparsity functional is better suited.

The joint sparsity as described above is a simple way to combine the information from several different correlated images in the reconstruction. Alternatively, a minimization of the 11 norm of a combined image e.g. sums of squares image or Roemer reconstruction can be used. The later approach can be applied by estimating the low resolution coil sensitivities (S) from the fully sampled central k-space data and applying these low resolution coil sensitivities in

Minimize ∥ψ(S^{H}S)⁻¹S^{H}x∥₁

subject to Fᵤxₙ=yₙ|_{acq}, n=1, . . . , N (2a)

Here x is the image estimate for all pixels and all coils. Uniform coil sensitivity profile is used for the body coil. The reconstructed images are then used to obtain high resolution coil sensitivity estimates. This procedure can be iteratively repeated setting the new high resolution coil sensitivity estimates in the next iteration.

This formulation presents one option to perform combined compressed sensing—parallel imaging reconstruction for solving the problem.

The sampling pattern is also compatible with combined compressed sensing—auto-calibration parallel imaging reconstruction as described in [3], which is referred to as SPIR-iT. This reconstruction can be performed by solving the problem

Minimize Σᵣ{square root over (Σₙ(ψxₙ(r))²)}

subject to Gy=y, Fᵤxₙ=y_{n|}_{_{acq}}, n=1, . . . , N (3)

where G is a kernel operator, obtained by calibration, which is applied for every k-space point and its entire neighbourhood across all coils. This is used to enforce consistency with the calibration data at each k-space location. The vector y denotes the current estimate of the k-space data at all k-space locations and all coils.

The combined CS-PI reconstruction could be a way to further reduce the necessary data without sacrificing the resolution in the coil sensitivities.

### Implementation Examples of Technique 1:

### First Example

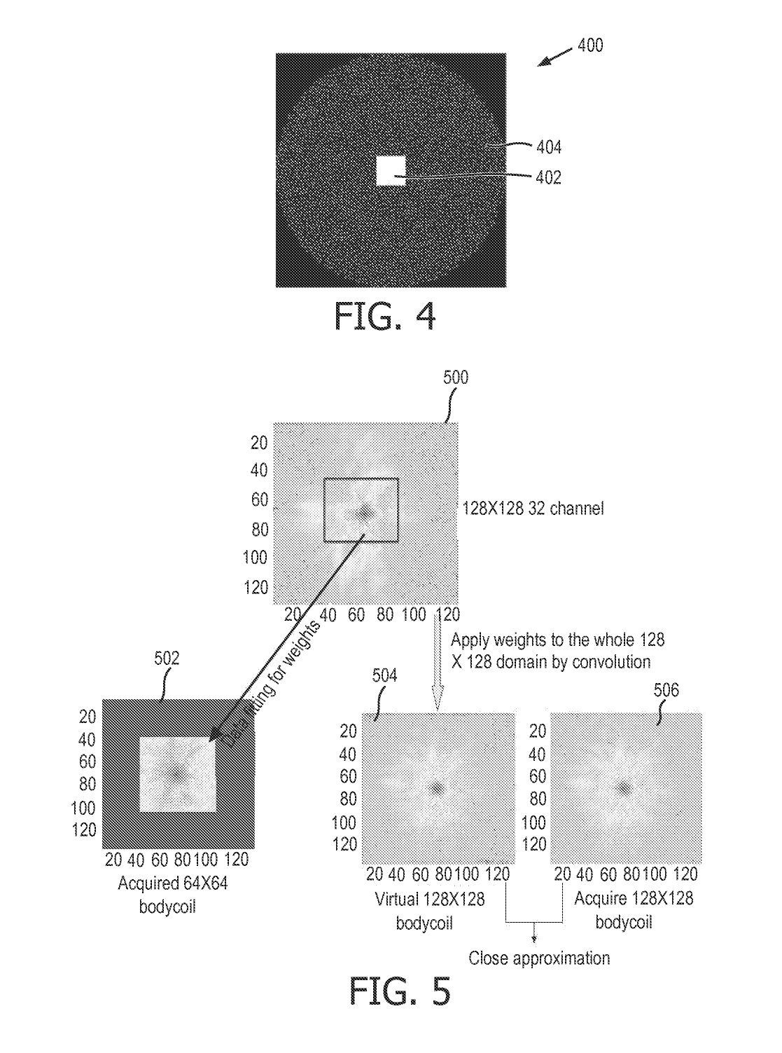

3D Cartesian data is acquired with the coil array and the body coil according to the k-space sampling pattern shown in FIG. 4. FIG. 4 shows an example of a k-space sampling pattern. The sampling pattern has two regions. In the sampling pattern 400 white space are areas of k-space which are sampled and dark areas are areas of k-space which are not sampled. The first region is labeled 402. Region 402 is a central kernel of k-space. Surrounding the central kernel 402 is a sparsely sampled region. The sparsely sampled region 404 this example is selected using a Poisson-disk distribution.

The same amount of data compared to a full sampling is acquired, resulting in the same total measuring time. In contrast to conventional sampling the present undersampling approach allows to increase kₘₐₓ to reach more far out in k-space to encode a smaller pixel size increasing spatial resolution.

The central part of k-space is fully sampled. The remaining k-space is undersampled using a random sampling pattern, or more appropriate according to a Poisson-Disk distribution. This results in a variable density sampling, which is desirable in CS. An elliptical shutter is applied for further sampling time reduction supporting the same spatial resolution in all directions. The images are reconstructed by solving the problem (1) or (2) and high resolution coil sensitivity maps are estimated from the reconstructed images. Second example:

3D Cartesian measurements are acquired as in Example (I). The fully sampled part of k-space is used for calibration of the kernel operator G used in Eq. (3). The operator G is obtained using all pixels in a given neighbourhood (e.g. 7×7). Reconstruction is performed by iteratively applying the operator G, the data consistency constraint and the sparsity constraint given in Eqns. (3) for example using a POCS type reconstruction as described in Ref. [2].

### Technique 2:

In this technique, the body coil is treated as an additional coil element of the phased array coil. Data fitting and convolution in k-space, GRAPPA like, is used to extrapolate the phased array coil to the body coil. The acquired low resolution body coil image is used for calibration.

FIG. 5 illustrates the proposed method. There are two steps. In the first step, the central k-space data from the phased array coil is used to fit the acquired data from the body coil. In this step, the weights are calculated. If a 3×3 kernel is used, then there are 3×3×Nch weights, where Nch is the number of coil elements of the phase array coil. In the second step, the calculated weights are applied to the whole k-space data from the phased array coil. This step results in k-space of the virtual body coil with the same resolution as the phased array coil.

FIG. 5 shows a collection of images which are used to illustrate the effectiveness of an embodiment of the invention. Image 500 is a 128×128 32 channel image that was acquired using a 32 element coil array. Image 502 shows an image reconstructed from body coil data. The image 502 is only a 64×64 element image of k-space. The black border surrounding the image is data that was not acquired. The black border shows the size of a 128×128 image. Image 504 is a composite image or a virtual body coil image which shows sampling in a 128×128 grid of k-space. Image 504 was constructed from images 502 and 500 by applying weights to the whole 128×128 domain by convolution. In contrast image 506 is an image of the k-space sampled and acquired by a body coil for the full 128'128 k-space. In comparing images 504 and 506 it can be seen that the virtual body coil image reasonably approximates the acquired body coil image 506.

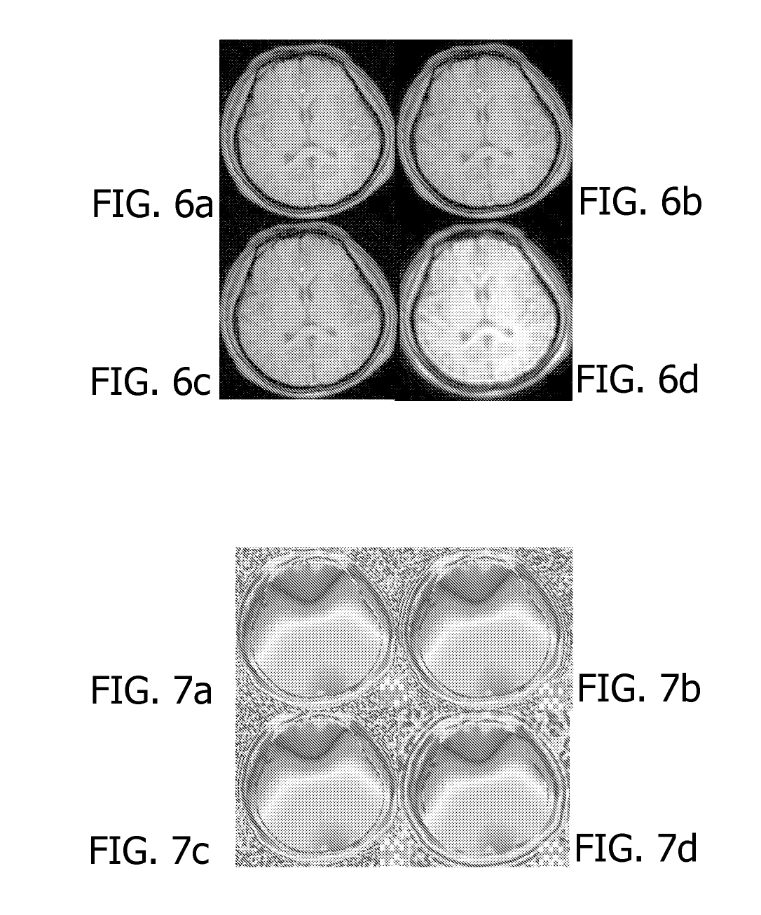

The images in FIG. 6 show an MRI image showing a slice through a subject's brain. The image in FIG. 6a was acquired using a 128×128 body coil image. Image 6a corresponds to image 506 of FIG. 5. FIG. 6b shows an image reconstructed using a 64×64 acquired body coil image. This body coil image was then reconstructed into a virtual body coil image as is shown in image 504 of FIG. 5. Similarly, FIG. 6c shows an image reconstructed using a 32×32 acquired body coil image. The 32×32 body coil image was reconstructed into a virtual 128×128 body coil image as is illustrated by image 504 of FIG. 5. To show a comparison in the increase in the quality of the images FIG. 6d shows an image where the acquired 64×64 body coil image was used for image reconstruction without constructing a 128×128 virtual body coil image. As can be seen with the images in FIG. 6a, b and c are very similar whereas the image in FIG. 6d is noticeably less sharp and shows less detail.

FIG. 7 shows a comparison of the phase of the images shown in FIG. 6. FIG. 7a corresponds to FIG. 6a, FIG. 7b corresponds to FIG. 6b, FIG. 7c corresponds to FIG. 6c and FIG. 7d corresponds to FIG. 6d. As with the comparison that was made in FIG. 6 it can be seen that FIGS. 7a, b and c display roughly the same information. FIG. 7d is very similar, but the resolution of the image is much lower.

It can be seen from FIGS. 6 and 7 that virtual body coil from 32×32 acquired data have higher resolution than acquired 64×64 body coil image in both magnitude and phase. FIGS. 2a)˜2c) are similar. And FIGS. 3a)˜3c) are similar.

### Technique 3:

This technique involves the computation of coil sensitivities to be used for SENSE unfolding. This technique may comprise:
A modified COCA scan consisting of low-resolution, fully sampled QBC data with high SNR, and high-resolution, in outer k-space areas possibly under-sampled synergy data, and
An iterative, non-linear algorithm for the joint reconstruction of images and coil sensitivities, including a regularization term based on the Sobolev norm to ensure smoothness of the sensitivity estimates.

The estimated coil sensitivities serve as input to subsequent SENSE reconstructions, while the estimated image can be used for regularization in the subsequent SENSE reconstruction.

This joint approach may make optimal use of the low- and high-resolution information provided by the newly designed COCA scan. The computed coil sensitivities are calibrated with respect to the QBC sensitivity, allowing the reconstruction of homogeneous images in SENSE or CLEAR scans. The total scan time of the newly designed COCA scan may not always be longer, because fewer signal averages are used for the acquisition of the synergy data, and some under-sampling can be applied in outer k-space areas.

The term ‘synergy coil’ as used herein is equivalent with the term coil array. Synergy data is data obtained using a synergy coil.

In parallel MRI, accurate coil sensitivity estimates are required to reconstruct aliasing-free images. Generally, these are computed on the basis of fully sampled, low-resolution data, which are acquired either separately (reference pre-scan such as the COCA scan) or jointly with the under-sampled imaging data (auto-calibration). Alternatively, a joint reconstruction of images and coil sensitivities may be performed. Existing approaches exploit the a priori assumption that coil sensitivities are smooth functions to regularize the non-linear reconstruction problem either by using a polynomial model for the sensitivities, as in JSENSE, or by penalizing their Sobolev norm with a non-linear inverse algorithm.

This method to compute coil sensitivity estimates using reconstruction software consists in dividing the images obtained from each synergy coil by the Quadrature Body Coil (QBC) image, after application of some suitable filters. A QBC coil may also be referred to as a body coil. This method requires reference images (COCA scan) with a high SNR, to avoid instabilities due to noise, and with low resolution, to avoid division by almost zero in voxels with little signal. Coil sensitivity estimates based solely on such low-resolution data suffer from insufficient accuracy, especially at the boundaries of the object where the sensitivity gradient may be the highest. As a consequence, application of high SENSE factors (>2 in 2D imaging) may be hampered.

Applying the current methodology to high-resolution data would result in an undesired substantial increase in scan time for the COCA scan and may yield poor sensitivity estimates in voxels with little signal. This invention proposes an alternative that yields high-resolution, accurate coil sensitivity estimates without increasing the acquisition time of the COCA scan.

While this technique is based on a joint estimation approach, it may solve a current drawback of joint estimation methods. Indeed, in all the above mentioned joint estimation methods, only the product of image and coil sensitivity is uniquely defined. As a consequence, the resulting coil sensitivity estimates are lacking a well-established reference, and the corresponding image reconstructions have undesired intensity variations. By contrast, the proposed invention computes coil sensitivity estimates that are calibrated with respect to the QBC, which is more desirable for the reconstruction of parallel imaging data.

This method may use a modified (3D) COCA scan consisting of:
low-resolution, fully sampled QBC data with high SNR (as current),
high-resolution, in outer k-space areas possibly under-sampled synergy coil data,

In this method, a joint reconstruction of images and coil sensitivities is performed using an iterative, non-linear algorithm. A regularization term based on the Sobolev norm of the coil sensitivities is applied to constrain the solution and ensure the smoothness of the sensitivity estimates. In the subsequent SENSE reconstructions, the coil sensitivities serve then as input to construct the SENSE unfolding matrix, while the images can be used for regularization.

This joint approach makes optimal use of the low- and high-resolution information provided by the newly designed COCA scan. The use of a Sobolev norm enables the reconstruction of artifact-free sensitivities and images. The computed coil sensitivities are well defined with respect to the sensitivity of the QBC, so that subsequent SENSE reconstructions yield images having the same signal homogeneity as would be obtained with a QBC acquisition. The total scan time of the newly designed COCA scan is not necessarily increased, because fewer signal averages are used for the acquisition of the synergy coil data, and some under-sampling can be applied in outer k-space areas.

The method comprises a new sampling scheme for the COCA scan, and a new reconstruction algorithm for the computation of the coil sensitivities.

### New Design of the COCA Scan:

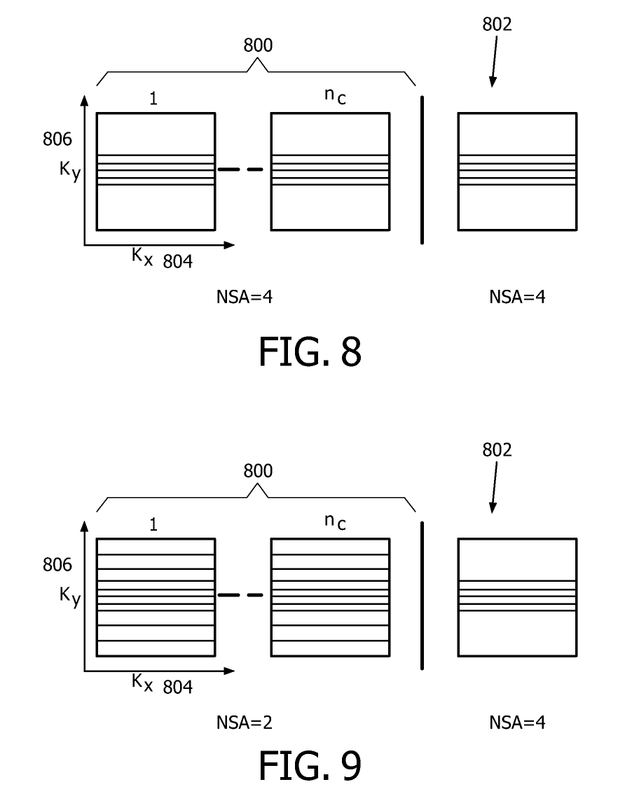

Currently, the sampling strategy of the COCA scan is designed to acquire only low-frequent components with a large number of averages, both for the synergy coils and the QBC (FIG. 8). In the proposed new sampling scheme, low-frequent and high-frequent components are acquired for the synergy coils, with the number of averages reduced to keep the scan time constant (FIG. 9). A moderate under-sampling factor (i.e. 9) can be applied in the outer k-space areas to reach a compromise between scan time and number of high-frequent components.

FIGS. 8 and 9 illustrate the location of k-space samples acquired in a COCA scan (FIG. 8) and in a scan according to an embodiment of the invention (FIG. 9). The blocks labeled 800 show the sampling in k-space for the individual coil elements of the coil array 800. The blocks 802 represent the space sampled in k-space for the body coil. K-space sampling in the x-direction is labeled 804 and k-space sampling in the y-direction is labeled 806. In FIG. 9 it can be seen that for the coil array 800 there is much more sampling in k-space. This allows the performance of a parallel imaging method without fully sampling the body coil in k-space.

### Coil Sensitivity Computation:

In the reconstruction step, full resolution images I and coil sensitivities S are to be computed from the synergy coil data dₛ and the QBC data d_{q}, according to the equations:

dₛ=PₛFSI (4)

d_{q}=P_{q}FI (5)

Here, F denotes the full-resolution Fourier transform, and Pₛ and P_{q} are projection matrices that map the position of the acquired samples onto the full sampling matrix, for the synergy coil and the QBC respectively.

Joint least-squares estimation of S and I yields the following non-linear minimization problem:

$$Sob ( A ) = {\sum }_{j} {‖ {w}_{j} {\hat{A}}_{j} ‖}^{2} , \qquad ( 7 )$$

The matrices Ψₛ and Ψ_{q} represent the covariance matrices of the noise in the synergy coils and the QBC respectively. The number of parameters to be estimated is much higher than the number of data samples, so that the inverse problem described by Eq. 6 is not well-posed. To solve this issue, a regularization method is applied. At each iteration of a Newton-type minimization algorithm, a penalty term based on the Sobolev norm of the coil sensitivities is added to Eq. 6. The weight of this penalty term is decreased progressively. A Sobolev norm of the form is used:

$${min}_{( I , S )} {( {d}_{s} - {P}_{s} FSI )}^{H} {Ψ}_{s}^{- 1} ( {d}_{s} - {P}_{s} FSI ) + {( {d}_{q} - {P}_{q} FI )}^{H} {Ψ}_{q}^{- 1} ( {d}_{q} - {P}_{q} FI ) \qquad ( 6 )$$

where w are weights increasing exponentially with the frequency index and Â is the Fourier transform of the vector A.

The choice of the sampling strategy for the COCA scan is reflected by the projection matrices Pₛ and P_{q}. Although the application of the joint estimation method is not restricted to specific sampling strategies, it was shown to yield good results with the sampling trajectories detailed above. Alternative sampling strategies that fulfill the requirements with respect to SNR and resolution may be found, especially non-Cartesian trajectories such as 3D radial.

Because of the use of QBC data and the inclusion of equation (5) into the minimization problem (6), the proposed joint estimation algorithm computes a high-resolution image I that has the same signal intensity as the corresponding QBC image. Hence, the coil sensitivity estimates S are well-defined with respect to the QBC.

The primary outputs of the described reconstruction algorithm are the coil sensitivities S, which can be used for unfolding in subsequent SENSE reconstructions. However, the full-resolution image I is also of interest, since it can be used for regularization in the subsequent SENSE reconstructions.

The proposed reconstruction algorithm can find applications on its own for the reconstruction of under-sampled data in SENSE acquisitions with a variable density sampling scheme.

### Example

This technique was evaluated in a multi-slice 2D phantom experiment on a 1.5 T scanner with a 5-element cardiac coil. A 2D protocol derived from the current 3D protocol of the COCA scan was devised, with the following parameters: FOV=400×250 mm, slice thickness=7 mm, TE=1.59 ms, TR=6.5 ms, flip angle=7°, scan technique: FFE. With this protocol, a standard COCA scan (COCA₀) with a resolution of 6.25×6.25 mm was obtained with a scan matrix of 40 phase encoding lines, in combination with 32 signal averages in order to obtain a SNR similar to that of a 3D sequence. Then, an alternative COCA scan (COCA₁) involving the same scan time and consisting of 160 phase encoding lines, in combination with 8 signal averages, was used to obtain fully sampled, high-resolution synergy coil data (1.56×1.56 mm). Lastly, a further modified COCA scan (COCA₂) yielding a 10% reduction of scan time and consisting of 128 phase encoding lines, in combination with 8 signal averages, was used to obtain under-sampled, high resolution coil data (1.56×1.56 mm). In the two latter cases, the QBC data were the same as in COCA₀. The parameters of the different COCA scans are summarized in Table. 1.

TABLE 1
Parameters of the different COCA scans.

| | Nb of phase encoding | | | |
|---|---|---|---|---|
| | steps | Resolution | NSA | Scan time |
| COCA₀ | 40 | 6.25 × 6.25 mm | 32 | 100% |
| COCA₁ | 160 | 1.56 × 1.56 mm | 8 | 100% |
| COCA₂ | 128 | 1.56 × 1.56 mm | 8 | 90% |

The COCA₀ data were used to compute coil sensitivities with the standard method. The joint estimation method was applied to compute coil sensitivities from the COCA₁ and COCA₂ data.

Then, under-sampled data with an acceleration factor of 4 were acquired, using a turbo spin-echo sequence (TE=70 ms, TR=309 ms, TSE factor=16). SENSE reconstruction was performed with the coil sensitivities obtained with the 3 different COCA scans. To facilitate comparison, the same low-resolution image was used in all reconstructions for regularization, so that only the differences in the coil sensitivities had an effect on the reconstruction results.

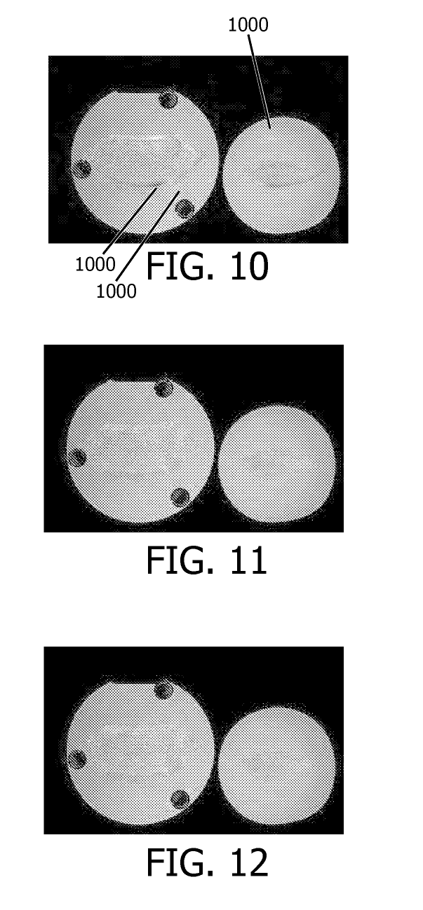

Reconstruction results for the TSE phantom data are presented in FIGS. 10 through 12, for the three different coil sensitivity estimates.

FIG. 10 shows a SENSE reconstruction from a fourfold undersampled dataset with the standard coil sensitivities derived from a standard COCA scan. The artifacts labeled 1000 are fold-over artifacts.

FIG. 11 shows the same image as shown in FIG. 10 except the alternative coil sensitivities are derived using the scan COCA₁ according to an embodiment of the invention. The fold-over artifacts visible in FIG. 10 are not visible in FIG. 11.

FIG. 12 shows the same image as FIGS. 10 and 11 but using the COCA₂ method to drive the alternative coil sensitivities. Also in FIG. 12 the fold-over artifacts are also not visible.

With the standard coil sensitivities derived from COCA₀, fold-over artifacts are visible in the two water bottles, arrows 1000 in FIG. 10. These artifacts cannot be seen on the images reconstructed with the alternative coil sensitivities, derived either from COCA₁ or COCA₂. Interestingly, no visible difference can be seen between the results obtained from COCA₁ and COCA₂, although in the latter case the COCA data were under-sampled and the scan time was slightly reduced. Furthermore, although the SNR of the synergy data used in COCA₁ and COCA₂ is half the one as for COCA₀, no increase of the noise level in the corresponding reconstructed SENSE images can be observed.

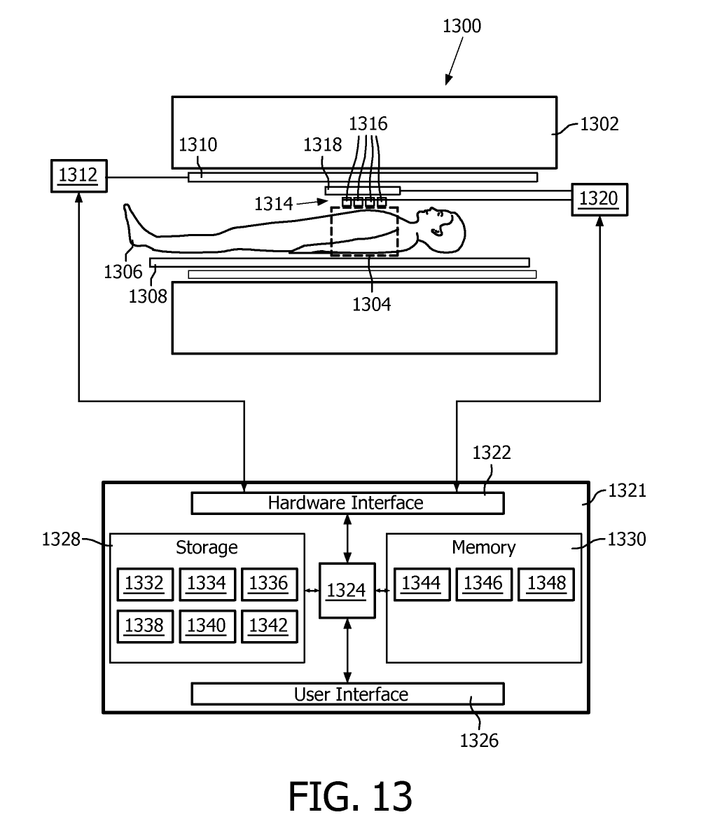

FIG. 13 shows an embodiment of a magnetic resonance imaging system 1300 according to an embodiment of the invention. The magnetic resonance imaging system 1300 comprises a magnet 1302. Within the magnet 1302 there is an imaging zone 1304. The imaging zone 1304 is a zone where the magnetic field of the magnet 1302 is uniform enough to perform magnetic resonance imaging. The subject 1306 can be seen reposing on a subject support 1308 with a portion of the subject 1306 within the imaging zone 1304. Also within the bore of the magnet 1302 is a magnetic field gradient coil 1310. The magnetic field gradient coils typically comprise three separate gradient coil systems for the x, y, and z-directions. Typically the z-direction is aligned with the magnetic field lines within the imaging zone 1304. A gradient coil power supply 1312 is shown as being connected to the magnetic field gradient coil 1310.

Above the imaging zone 1304 is a coil array 1314. The coil array 1314 is shown as being comprised of four coil elements 1316. The actual number of coil elements 1316 and their arrangement space depends upon the geometry being imaged by the coil array 1314. Above the coil array 1314 is shown a body coil 1318. Both the body coil 1318 and the elements 1316 of the coil array 1314 are shown as being connected to a radio frequency transceiver 1320. The radio frequency transceiver 1320 may be replaced in some embodiments by separate transmitters and receivers. Both the gradient coil power supply 1312 and the radio frequency transceiver 1320 are shown as being connected to a hardware interface 1322 of a computer 1321.

Within the computer 1321 a processor 1324 is able to send and receive instructions from the hardware interface 1322. By means of the hardware interface 1322 the CPU 1324 is able to control the operation and function of the magnetic resonance imaging system 1300. The processor 1324 is also connected to a user interface 1326 which may be adapted for displaying data or renderings of magnetic resonance imaging to a user. The user interface 1326 may also be adapted for receiving commands or instructions from a user for operating the magnetic resonance imaging system 1300. The processor 1344 is also connected to computer storage 1328 and computer memory 1330. Although a single computer 1321 and a single processor 1324 are shown it is understood that the terms a computer and a processor may refer to a plurality of computers and/or processors.

In the computer storage 1328 is stored a pulse sequence 1332. A pulse sequence as used herein encompasses a set of instructions for operating a magnetic resonance imaging system 1300 for acquiring magnetic resonance imaging data 1340. The storage 1328 further contains a set of coil array date 1334 that was acquired with the magnetic resonance imaging system 1300. The computer storage 1328 further contains body coil data 1336 that was acquired by the magnetic resonance imaging system 1300. The computer storage 1328 further contains a coil sensitivity map 1338 that was calculated or reconstructed using the set of coil array data 1334 and the body coil data 1336. The computer storage 1328 further contains magnetic resonance imaging data 1340 acquired by the magnetic resonance imaging system 1300. Finally the computer storage 1328 also contains a magnetic resonance image 1342 which is reconstructed using the magnetic resonance imaging data 1340 and the coil sensitivity map 1338.

The computer memory 1330 contains several modules belonging to a computer program product for running and operating the magnetic resonance imaging system 1300. The computer memory 1330 contains a system control module 1344. The system control module 1344 controls the operation and functioning of the magnetic resonance imaging system 1300. The computer memory 1330 further contains a sensitivity map reconstruction module 1346. The sensitivity map reconstruction module 1346 contains instructions for use by the processor 1324 to calculate a coil sensitivity map 1338 using the body coil data 1336 and the set of coil array data 1334. The memory 1330 also contains an image reconstruction module 1348. The image reconstruction module 1348 contains instructions for the processor 1324 to reconstruct a magnetic resonance image 1342 using the magnetic resonance imaging data 1340 and the coil sensitivity map 1338. While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

400 k-space sampling pattern
402 central kernel of k-space
404 sparsely sampled region
500 128 by 128 32 channel k-space image
502 64 by 64 k-space image
504 composite or virtual 128 by 128 k-space image
506 acquired 128 by 128 k-space image
800 sampling for coil array
802 sampling for body coil
804 sampling in k-space in x direction
806 sampling in k-space in y direction
1000 fold-over artifacts
1300 magnetic resonance imaging system
1302 magnet
1304 imaging zone
1306 subject
1308 subject support
1310 magnetic field gradient coil
1312 gradient coil power supply
1314 coil array
1316 antenna element
1318 body coil
1320 radio frequency transceiver
1321 computer
1322 hardware interface
1324 processor
1326 user interface
1328 computer storage
1330 computer memory
1332 pulse sequence
1334 set of coil array data
1336 body coil data
1338 coil sensitivity map
1340 magnetic resonance imaging data
1342 magnetic resonance image
1344 system control module
1346 sensitivity map reconstruction module
1348 image reconstruction module

1. A computer program product comprising machine executable instructions for performing a method of acquiring a magnetic resonance image, the method comprising the steps of:
acquiring a set of coil array data of an imaging volume using a coil array, wherein the set of coil array data comprises coil element data acquired for each antenna element of the coil array;
acquiring body coil data of the imaging volume with a body coil, wherein the body coil data and/or the array coil data are sub-sampled;
wherein the coil element data and the body coil data are both undersampled in k-space and are undersampled to a different degree, and
reconstructing a set of coil sensitivity maps using the set of coil array data and the body coil data, wherein there is a coil sensitivity map for each antenna element of the coil array;
acquiring magnetic resonance imaging data of the imaging volume using a parallel imaging method; and
reconstructing the magnetic resonance image using the magnetic resonance imaging data and the set of coil sensitivity maps.

2. The computer program product of claim 1, wherein the set of body coil data is sub-sampled by undersampling in k-space.

3. The computer program product of claim 1, wherein the set of coil array data is sub-sampled by undersampling in k-space.

4. (canceled)

5. The computer program product of claim 2, wherein the undersampling of k-space of the body coil is non-uniformly distributed in k-space.

6. The computer program product of claim 1, wherein the sub-sampling comprises sampling k-space for values of k below a predetermined threshold.

7. The computer program product of claim 1, wherein the set of coil sensitivity maps is reconstructed using a regularization technique.

8. The computer program product of claim 7, wherein the regularization is performed on subsets of the set of coil array data, wherein the subsets are determined by grouping coil element data from physically adjacent antenna elements of the coil array,

9. The computer program product of claim 1, wherein the k-space of the body coil data is undersampled by acquiring k-space data from a central kernel using the body coil.

10. The computer program product of claim 9, wherein the set of coil sensitivity maps and a composite image are jointly estimated using a non-linear estimation.

11. The computer program product of claim 10, wherein the method further comprises the steps of:
calculating a set of weighting factors for each of die antenna elements of the coil array using the k-space data from the central kernel:
calculating the composite image by applying the set of weighting factors to each image of a set of coil array images, wherein the set of coil array images is reconstructed from the set of coil array data; and
wherein the set of coil sensitivity maps is calculated using the composite image and the set of coil array data,

12. The computer program product of claim 1, wherein the parallel imaging method is any one of the following: SENSE, PARS, and Simultaneous Acquisition of Spatial Harmonics, or GRAPPA.

13. The computer program product of claim 1, wherein undersampling of the He-space is performed using any one of the following: a predetermined sampling pattern, a random sampling pattern, by sampling k-space elements determined by a Poisson-disk distribution, and by sampling fully a kernel of k-space below a predetermined value of k and sparsely sampling above the value of k.

14. A computer-implemented method of acquiring a magnetic resonance image, the method comprising the steps of:
acquiring set of coil array data an imaging volume using a coil array, wherein the set of coil array data comprises coil element data acquired for each antenna element of the coil array;
acquiring body coil data of the imaging volume with a body coil, wherein the body coil data and/or the array coil data are sub-sampled, wherein the coil element data and the body coil data are both undersampled in k-space and are undersampled to a different degree, and
reconstructing a set of coil sensitivity maps using the set of coil array data and the body coil data, wherein there is a coil sensitivity map for each antenna element of the coil array;
acquiring magnetic resonance imaging data of the imaging volume using a parallel imaging method; and
reconstructing the magnetic resonance image using the magnetic resonance imaging data and the set of coil sensitivity maps.

15. A magnetic resonance imaging system comprising:
a magnetic resonance imaging magnet generating a main magnetic field for orientating the magnetic spins of nuclei of a subject located within an imaging volume;
a magnetic field gradient coil for generating a gradient magnetic field for spatial encoding of the magnetic resonance signal of spins of nuclei within the imaging volume;
a gradient coil power supply for supplying current to the magnetic field gradient coil;
a radio frequency system for acquiring magnetic resonance imaging data, wherein the radio frequency system is adapted to connect to a body coil and a coil array;
a computer system comprising a processor, wherein the computer system is adapted for constructing images from the magnetic resonance imaging data and for controlling the operation of the magnetic resonance imaging system; and
a computer-readable storage medium containing instructions for execution by the processor, wherein when executed cause the processor to perform the steps of:
acquiring a set of coil array data of the imaging volume using the coil array, wherein the set of coil array data comprises coil element data acquired for each antenna element of the coil array;
acquiring body coil data of the imaging volume with the body coil, wherein the body coil data and/or the array coil data are sub-sampled; wherein the coil element data and the the body coil data are both undersampled in k-space and are undersampled to a different degree, and
reconstructing a set of coil sensitivity maps using the set of coil element data and the coil array data, wherein there is a coil sensitivity map for each antenna element of the coil array;
acquiring magnetic resonance imaging data of the imaging volume using a parallel imaging method; and
reconstructing the magnetic resonance image using the magnetic resonance imaging data and the set of coil sensitivity maps.
